(19) United States
(12) Patent Application Publication
(10) Pub. No.: US 2005/0243640 A1
(43) Pub. Date: Nov. 3, 2005

(54) Storing code in fragments

(76) Inventors: John C. Rudelic, Folsom, CA (US); Sujaya Srinivasan, Folsom, CA (US); Christopher N. Conley, Sacramento, CA (US)

Correspondence Address: TROP PRUNER & HU, PC, 8554 KATY FREEWAY, SUITE 100, HOUSTON, TX, 77024, US

(21) Appl. No.: 10/836,682

(22) Filed: Apr. 30, 2004

(51) Int. Cl. G11C 8/02

(52) U.S. Cl. 365/232

(57) ABSTRACT

In one embodiment of the present invention, a method includes storing a code object in a volume of an execute-in-place memory that includes at least one data object. In certain embodiments, the code object may be stored as a plurality of fragments. Further, the memory may support execution in place such that a processor may execute in place a first code fragment of a code object and execute in place a second code fragment of the code object from the memory, where the code fragments are non-contiguously stored in the memory.

### BACKGROUND

Block-alterable memories, such as flash memories, are often used for applications in which non-volatility and programmability are desired. Flash memory is a high-speed electrically erasable programmable read-only memory (EEPROM) in which erasing and programming (i.e., writing) is performed on blocks of data.

Systems using block-alterable memories such as flash memory typically require the use of management software to interface to the memory. For example, such management software for a flash memory file system includes a separate code manager and data manager for managing respectively, code objects and data objects stored in the memory. Examples of data objects are telephone or personal digital assistant (PDA) parameters, Motion Picture Experts Group, Layer 3 (MP3) files, or picture files, and streaming data such as voice recordings and voice tags. Code objects include JAVA™ applets and games and direct mapped non-executable files. Data objects are stored in a data volume in a fragmented form, where the size of each fragment is fixed (either through a user configurable option or by the flash file system), and control structures such as sequence tables maintain pointers to individual fragments to string the data together. In contrast, code objects are stored in a separate code volume and are stored contiguously so they can be executed in place (XIP). Updates and deletion of code objects require several reclaim operations to occur so that all free space can be maintained contiguously. Further, maintaining code and data separately creates limitations on use of memory space. A need thus exists to more efficiently use memory space in a block-alterable memory.

### BRIEF DESCRIPTION OF THE DRAWINGS

FIG. 1 is a block diagram of a portion of a system in accordance with one embodiment of the present invention.

FIG. 2 is a block diagram of a code volume in accordance with one embodiment of the present invention.

FIG. 3 is a block diagram of code fragments and control structures in accordance with one embodiment of the present invention.

FIG. 4 is a flow diagram of a method of storing code in accordance with one embodiment of the present invention.

FIG. 5 is a flow diagram of a method of executing code in accordance with an embodiment of the present invention.

FIG. 6 is a block diagram of a wireless device with which embodiments of the present invention may be used.

### DETAILED DESCRIPTION

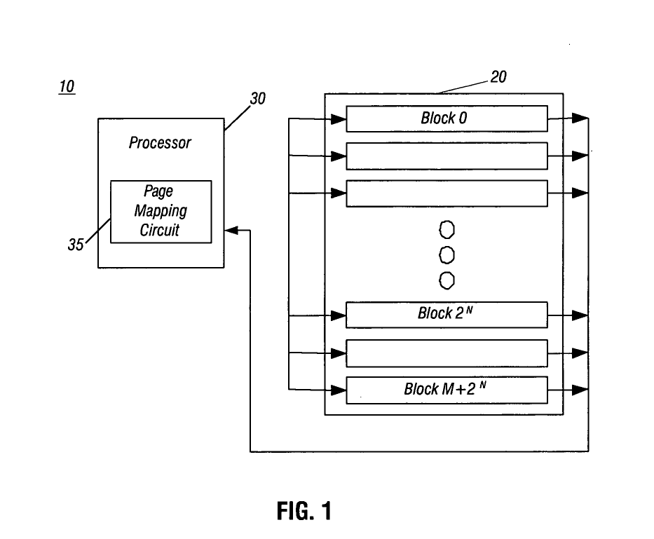

Referring to FIG. 1, shown is a block diagram of a portion of a system including a block-alterable memory in accordance with one embodiment of the present invention. System 10 may be any desired information handling system such as a cellular telephone, PDA, laptop computer, desktop computer, or the like. As shown in FIG. 1, block-alterable memory 20, which may be a flash memory device or other semiconductor or other storage device that may accommodate XIP operation, may include a memory array having a plurality of individual blocks. A block is a memory element that includes a number of rows and columns of memory cells. While the number of blocks in a memory array may vary, in certain embodiments featuring multi-level cells, 64 blocks may be present with each block of memory having 256 kilobytes (KB) to 1 megabyte (MB) of data storage, each of which may be separately erasable. Moreover, the memory array shown in FIG. 1 may be a single volume that includes both code objects and data objects, although the scope of the present invention is not so limited. In other embodiments, multiple volumes may be present in a memory device to separately store code objects and data objects.

As further shown in FIG. 1, a processor 30 may be coupled to memory device 20. In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

Processor 30 may be a central processing unit (CPU) of system 10. In one embodiment, processor 30 may be a stacked processor of a multi-chip memory system. Processor 30 may include a memory management unit (MMU), shown in FIG. 1 as a page mapping circuit 35. Such a MMU may be used to translate virtual or logical addresses into physical addresses. In certain embodiments, page mapping circuit 35 may include a translation look-aside buffer (TLB), page tables, and other mapping circuitry and tables that may be used to provide logical to physical addressing.

In certain embodiments, processor 30 may execute management software to control management of memory device 20. For example, such management software may include instructions to store both code and data objects in a fragmented manner in a single volume of memory device 20.

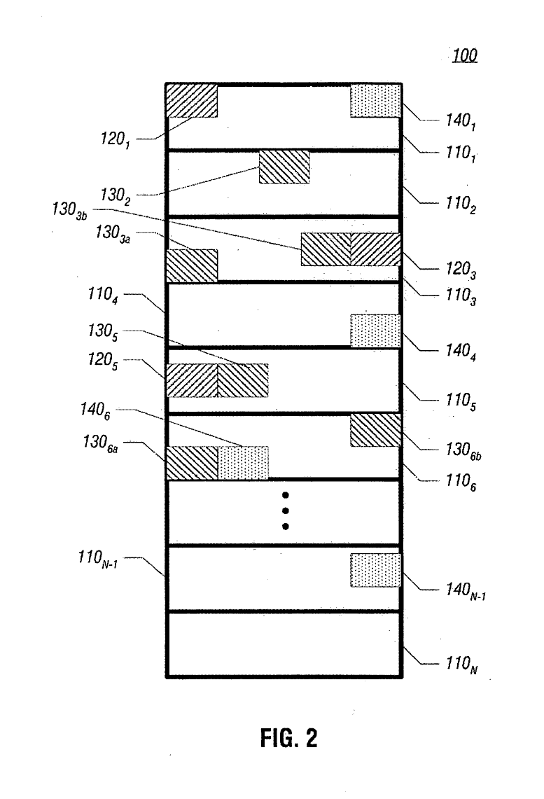

Referring now to FIG. 2, shown is a block diagram of a code volume of a memory device in accordance with one embodiment of the present invention. As shown in FIG. 2, code volume 100, which may be a volume managed by code management software, may include a plurality of blocks 110₁ through 110_{N}. A plurality of code objects, namely a first code object 120 (generically) and a second code object 130 (generically) may be stored in a fragmented manner in various blocks of code volume 100. Specifically, as shown in FIG. 2, various fragments of first code object 120 may be stored in portions of blocks 110₁ (i.e., code fragment 120₁), 110₃ (i.e., code fragment 120₃) and 110₅ (i.e., code fragment 120₅). Similarly, second code object 130 may be segmented into a plurality of fragments stored in various blocks of code volume 100. For example, as shown in FIG. 2, second code object 130 may include fragments within blocks 110₂, 110₃, 110₅, and 110₆ (i.e., respectively, fragment 130₂; fragments 130₃ₐ and 130_{3b}; fragment 130₅; and fragments 130₆ₐ and 130_{6b}). In such manner, code objects may be stored non-contiguously in one or more blocks of a block-oriented memory.

A plurality of control structures may be present in a fragmented code volume to provide access to the various code fragments. In one embodiment, such control structures may include segment tables that may be fragmented and stored in various locations within code volume 100. For example, as shown in FIG. 2, a control structure 140 (generically) may include a plurality of sequence tables stored in portions of blocks 110₁, 110₄, 110₆, and 110_{N-1} (respectively control structure fragments 140₁, 140₄, 140₆, and 140_{N-1}).

In various embodiments, the sequence tables may contain pointers to code fragments or to another sequence table. For example, sequence table 140₁ may be a level zero sequence table that points to certain code fragments. However, as additional code fragments are stored in code volume 100, sequence table 140₁ becomes full, and a level one sequence table may be created. For example, sequence table 140₄ may be created to point to one or more level zero sequence tables.

Also shown in FIG. 2 is block 110_{N}, which may be a spare block for code volume 100. In certain embodiments, spare block 110_{N} may be used for reclamation purposes. For example, to reclaim dirty space within code volume 100, management software may select a block that contains a large amount of dirty space. Any valid information within the selected block may be copied over to spare block 110_{N} so that the dirty block may be erased. In certain embodiments, the newly erased block may become the spare block, and control structures pointing to the valid information may be updated to now point to block 110_{N}.

While the size of code and data fragments may vary in different embodiments, in one embodiment, code fragments may be selected to be equal to a size of an operating system (OS) page (or multiples thereof) which, in certain embodiments may be 4 KB. If the OS supports paging such that a page can be executed in place from the memory device, storing code objects in fragments provides benefits of XIP as well as the advantages of fragmented storage.

In various embodiments, code and data may both be maintained using a fragmented mechanism. In such embodiments, information stored in a control structure may indicate whether an object is a code or data object, as will be discussed further below. By storing code objects in a fragmented manner, management and updating of code may be more efficient. In addition, management software may be simplified, since the same mechanism may be used to store both code and data objects.

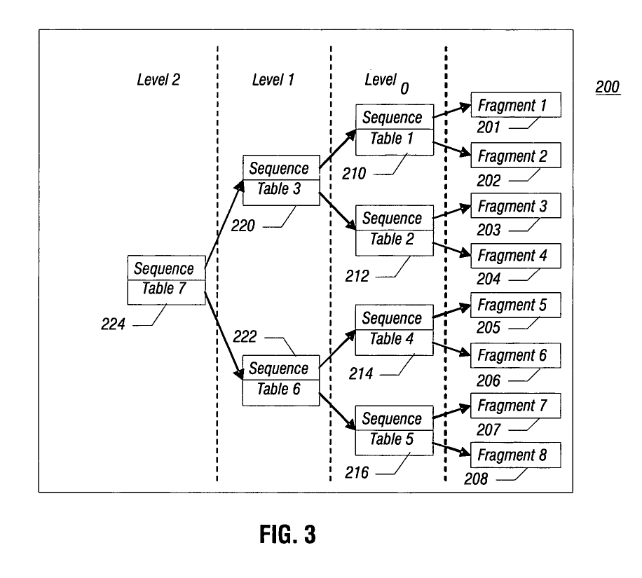

Referring now to FIG. 3, shown is a block diagram of a code volume 200 in accordance with one embodiment of the present invention. As shown in FIG. 3, code volume 200 may include a plurality of code fragments 201-208 (respectively, code fragment 201 through code fragment 208) that may be accessed using control structures formed of a plurality of sequence tables. Specifically, as shown in FIG. 3 a first level (namely a level zero) includes a plurality of sequence tables. The level zero sequence tables shown in FIG. 3 include a first sequence table 210 (i.e., sequence table 1), a second sequence table 212 (i.e., sequence table 2), a third sequence table 214 (i.e., sequence table 4), and a fourth table sequence 216 (i.e., sequence table 5). Each of sequence tables 210, 212, 214 and 216 may be a level zero sequence table that points to one or more code fragments within code volume 200.

In certain embodiments, an entry in these first level sequence tables may point to a given one of the code fragments. Each entry may also include status information, such as a control bit, to indicate whether the fragment being pointed to by the entry is a code fragment or a data fragment. However, in other embodiments, another type of control structure may be used, and a different means of identifying a fragment as code or data may be implemented.

As additional code fragments are placed into code volume 200, a sequence table may become full. When a level zero sequence table is filled, a level one sequence table is created, which may point to the level zero sequence table (and additional level zero sequence tables as they become similarly filled). Such sequence tables may be sequentially generated such that when a level one sequence table becomes full, a level two sequence table is created which may point to the level one sequence table (in addition to other level one sequence tables). For example, in the embodiment shown in FIG. 3, a first level one sequence table 220 (i.e., sequence table 3) may point to two level zero sequence tables, namely sequence table 210 and sequence table 212. Similarly, a second level one sequence table 222 (i.e., sequence table 6) may point to level zero sequence tables 214 and 216. Furthermore, when level one sequence table 220 becomes full, a level two sequence table 224 may be created, which may point to level one sequence table 220 (and a second level one sequence table 222). In various embodiments, the highest level sequence table may include the root of the code object.

While shown in the embodiment of FIG. 3 as each pointing to two code fragments, it is to be understood that in other embodiments level zero sequence tables may point to many more than two fragments. Similarly, the level one sequence tables shown in FIG. 3 each point to two level zero sequence tables, although the scope of the present invention is not so limited. Similarly, it is to be understood that a level two sequence table may point to more than two level one sequence tables. Furthermore, it is to be understood that in other embodiments additional levels of sequence tables may be present, and more or fewer sequence tables may be present in each level. Also, it is to be understood that the eight code fragments shown in FIG. 3 are for purposes of example only, and in other embodiments additional fragments may be present. Similarly, while discussed with respect to FIG. 3 as including code fragments, it is to be understood that in other embodiments a combination of code and data fragments may be present in volume 200.

Thus in various embodiments, better performance in management of code and data objects may be realized. Further, by fragmenting code objects, operating systems may be driven to support paging in of XIP code objects from a semiconductor or other XIP memory. Embodiments may be used in connection with any storage of data and code in volatile or nonvolatile memory such as a flash device. Examples of such storage may include parameter/data storage, file management and code storage in a cellular telephone or file and code storage in a personal digital assistant (PDA), or the like, although the scope of the present invention is not limited in this respect.

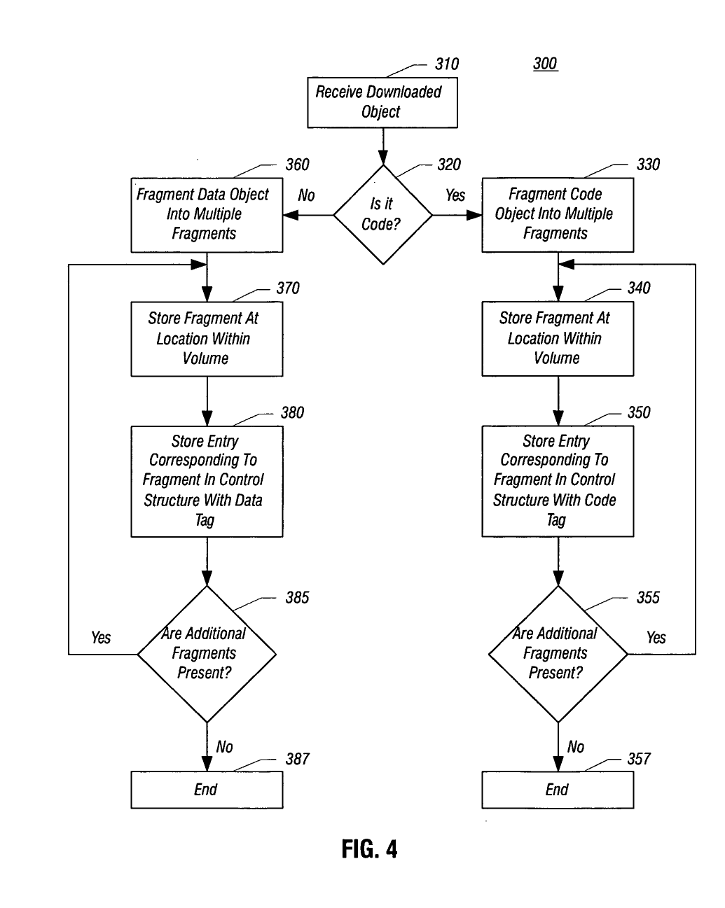

Referring now to FIG. 4, shown is a flow diagram of a method in accordance with one embodiment of the present invention. As shown in FIG. 4, method 300 may be used to receive downloaded objects in a device having a memory in accordance with an embodiment of the present invention. For example, method 300 may be used to receive downloaded code or data objects in a cellular phone, PDA, or the like.

Still referring to FIG. 4, method 300 may begin by receiving a downloaded object (block 310). Next it may be determined whether the object is code or data (diamond 320). If it is determined that the downloaded object is code, the code object may be fragmented into multiple fragments (block 330). For example, in one embodiment a code object may be segmented into a plurality of fragments, each having a fragment size equal to an operating system page, although the scope of the present invention is not so limited. Then, the multiple fragments may be stored at a location within a volume of the memory (block 340). For example, a fragment may be stored at any location within a block of a volume that is determined using management software in accordance with an embodiment of the present invention. Various considerations, such as block usage, wear leveling, and the like may be taken into account in determining where to place a given fragment. When a fragment is stored in the volume, an entry corresponding to the fragment may also be stored in a control structure (block 350). For example, an entry into a sequence table may be created that corresponds to the fragment. More so, in certain embodiments, such an entry may include a tag or other identifier to indicate that the fragment it represents is part of a code object. Then it may be determined whether additional fragments are present (diamond 355). If so, control returns block 340 and the method continues thereat. Alternately, if no additional fragments are present, the method may be concluded at block 357.

If instead it is determined at diamond 320 that the downloaded object is data rather than code, control may pass to block 360, where the data object may be fragmented into multiple fragments. Then the fragment may be stored at a location within a volume of the memory device (block 370). Further, an entry corresponding to the fragment may be stored in a control structure with a tag that identifies the stored fragment as being part of a data object (block 380). At diamond 385, it may then be determined whether additional fragments are present. If so, control passes back to block 370. Alternately, the method may conclude at block 387.

While discussed in the embodiment of FIG. 4 as storing both code and data objects in a single volume, it is to be understood that in other embodiments different volumes may be used for code objects and data objects.

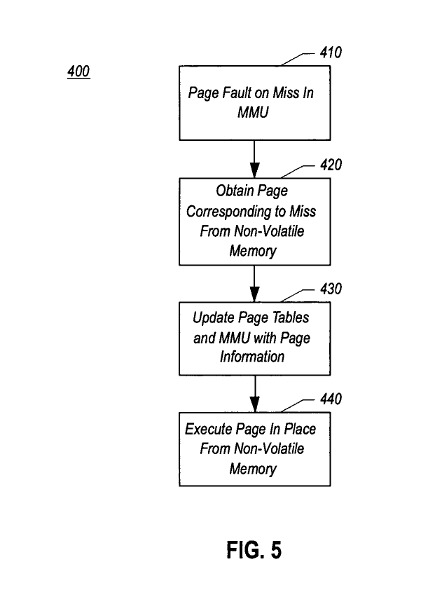

Referring now to FIG. 5, shown is a flow diagram of a method in accordance with one embodiment of the present invention. Method 400 may be performed while executing code in place from a memory in accordance with an embodiment of the present invention. While executing such code in place from the memory, a page fault may occur (block 410). For example, such a page fault may occur when an address for code to be executed does not exist in the page tables of the MMU (i.e., a page miss). Such a miss may occur, for example, when code in a first code fragment branches to code in a second, non-contiguous code fragment. Accordingly, the page to which the missed address corresponds may be obtained from non-volatile memory (block 420). Using the information obtained from the non-volatile memory, page tables and the MMU may be updated with page information for the new page of memory (block 430). Finally, the page may be executed in place from the non-volatile memory (block 440). In such manner, different fragments of code segments may be executed in place directly from the memory, improving performance.

Embodiments of the present invention may be performed in a variety of locations within or external to a storage system. For example, software to store fragmented code objects may be executed in circuitry embedded inside a monolithic semiconductor memory device, or a software algorithm executed by a controller stacked with memory inside a multi-chip memory subsystem package. For example, in one embodiment an algorithm may be implemented in microcode of a flash memory device, such as within a coprocessor within the device. Alternately, a software algorithm may be executed by an external processor separate from the memory subsystem.

Embodiments of the present invention may be implemented in code and may be stored on a storage medium having stored thereon instructions which can be used to program a system, such as a wireless device to perform the instructions. The storage medium may include, but is not limited to, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs), erasable programmable read-only memories (EPROMs), flash memories, electrically erasable programmable read-only memories (EEPROMs), magnetic or optical cards, a silicon-oxide-nitride-oxide-silicon (SONOS) memory, a phase-change or ferroelectric memory, or any type of media suitable for storing electronic instructions.

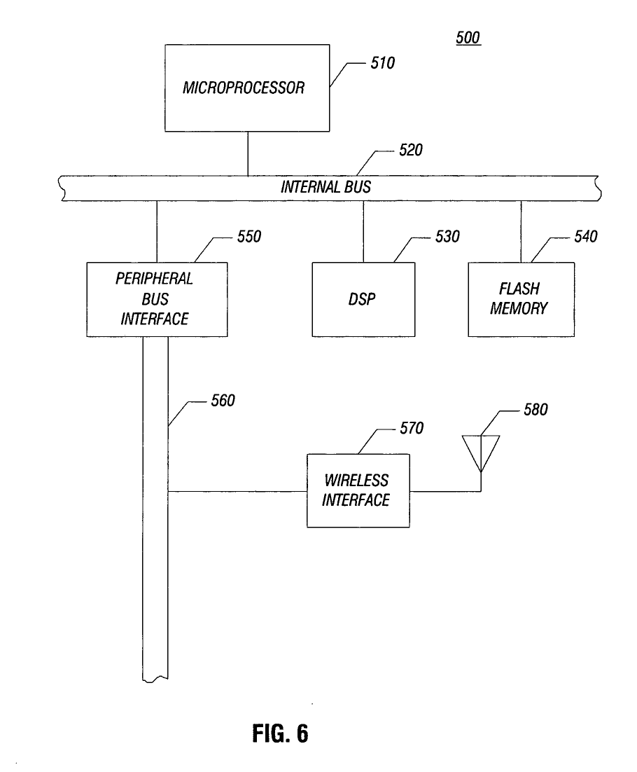

FIG. 6 is a block diagram of a wireless device with which embodiments of the invention may be used. As shown in FIG. 6, in one embodiment wireless device 500 includes a processor 510, which may include a general-purpose or special-purpose processor such as a microprocessor, microcontroller, application specific integrated circuit (ASIC), a programmable gate array (PGA), and the like. Processor 510 may be coupled to a digital signal processor (DSP) 530 via an internal bus 520. A flash memory 540 which may store code and data fragments in accordance with an embodiment of the present invention also may be coupled to internal bus 520. In other embodiments, a different type of non-volatile memory may be present.

As shown in FIG. 6, microprocessor device 510 may also be coupled to a peripheral bus interface 550 and a peripheral bus 560. While many devices may be coupled to peripheral bus 560, shown in FIG. 6 is a wireless interface 570 which is in turn coupled to an antenna 580. In various embodiments antenna 580 may be a dipole antenna, helical antenna, a global system for mobile communications (GSM) antenna or another such antenna.

Although the description makes reference to specific components of device 500, it is contemplated that numerous modifications and variations of the described and illustrated embodiments may be possible. More so, while FIG. 6 shows a block diagram of a wireless device, it is to be understood that embodiments of the present invention may be implemented in a system such as a personal computer, server, or the like. In such embodiments, a flash memory may be coupled to a Peripheral Component Interconnect (PCI) bus, as defined by the PCI Local Bus Specification, Production Version, Revision 2.1 dated in June 1995, or other such bus.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
storing a code object in a volume of an execute-in-place memory that includes at least one data object.

2. The method of claim 1, further comprising storing the code object as a plurality of fragments.

3. The method of claim 2, wherein the plurality of fragments each comprise a page size of an operating system or a multiple of the page size.

4. The method of claim 2, further comprising storing information corresponding to a location of each of the plurality of fragments and a code indicator in at least one control structure.

5. The method of claim 1, further comprising executing the code object in place from the volume.

6. The method of claim 1, wherein the execute-in-place memory comprises a non-volatile memory.

7. A method comprising:
storing a code object as a plurality of fragments in an execute-in-place memory.

8. The method of claim 7, further comprising storing the code object in a volume of the execute-in-place memory that includes at least one data object.

9. The method of claim 7, further comprising storing a tag in a control structure to indicate that the code object includes code.

10. The method of claim 7, further comprising storing the plurality of fragments non-contiguously in the execute-in-place memory.

11. A method comprising:
executing in place a first code fragment of a code object from a semiconductor memory; and
executing in place a second code fragment of the code object from the semiconductor memory.

12. The method of claim 11, further comprising branching to the second code fragment upon a branch condition in the first code fragment.

13. The method of claim 11, wherein the first code fragment and the second code fragment are stored non-contiguously in the semiconductor memory.

14. The method of claim 11, wherein the first code fragment and the second code segment are stored in a volume of the semiconductor memory with at least one data fragment of a data object.

15. The method of claim 11, further comprising obtaining a first physical address for the first code fragment from a first control structure of the semiconductor memory.

16. The method of claim 15, further comprising providing the first physical address to a memory management unit of a processor.

17. The method of claim 15, further comprising obtaining a second physical address for the second code fragment from a second control structure of the semiconductor memory.

18. An article comprising a machine-accessible storage medium containing instructions that if executed enable a system to:
store a code object as a plurality of fragments in an execute-in-place memory.

19. The article of claim 18, further comprising instructions that if executed enable the system to store a tag in a control structure to indicate that the plurality of fragments includes code.

20. The article of claim 18, further comprising instructions that if executed enable the system to store the plurality of fragments non-contiguously in the execute-in-place memory.

21. The article of claim 18, further comprising instructions that if executed enable the system to provide a physical address corresponding to one of the plurality of fragments to a processor.

22. An apparatus comprising:
at least one storage device to store instructions to store a code object as a plurality of fragments in an execute-in-place memory.

23. The apparatus of claim 22, further comprising a memory management unit coupled to the at least one storage device to obtain a physical address corresponding to one of the plurality of fragments.

24. The apparatus of claim 22, wherein the at least one storage device comprises a non-volatile memory.

25. A system comprising:
at least one storage device to store instructions to store a code object as a plurality of fragments in an execute-in-place memory; and
a wireless interface coupled to the at least one storage device.

26. The system of claim 25, wherein the wireless interface comprises an antenna.

27. The system of claim 25, further comprising a memory management unit coupled to the at least one storage device to obtain a physical address corresponding to one of the plurality of fragments.

28. The system of claim 25, wherein the at least one storage device comprises the execute-in-place memory.

29. The system of claim 25, further comprising a processor coupled to the at least one storage device to execute the code object in place from the at least one storage device.

30. The system of claim 25, wherein the execute-in-place memory comprises a non-volatile memory coupled to the at least one storage device.
